(19) United States
(12) Patent Application Publication
(10) Pub. No.: US 2026/0202735 A1
(43) Pub. Date: Jul. 16, 2026

(54) OPTICAL PROXIMITY CORRECTION (OPC) METHOD AND MASK MANUFACTURING METHOD INCLUDING THE OPC METHOD

(71) Applicant: Samsung Electronics Co., Ltd., Suwon-si (KR)

(72) Inventors: Moojoon Shin, Suwon-si (KR); Yongsu Jung, Suwon-si (KR); Kyungjae Park, Suwon-si (KR); Yongju Jung, Suwon-si (KR)

(21) Appl. No.: 19/345,846

(22) Filed: Sep. 30, 2025

(30) Foreign Application Priority Data
Jan. 15, 2025 (KR) 10-2025-0006385

(51) Int. Cl. G03F 1/36; G03F 7/00

(52) U.S. Cl. CPC G03F 1/36; G03F 7/0005; G03F 7/70441

(57) ABSTRACT

Optical proximity correction (OPC) methods are provided. In one aspect, a method includes inputting a wave pattern layout based on a trigonometric function having a width, a height, and power as variables, generating evaluation points on the wave pattern layout, and optimizing the wave pattern layout based on the evaluation points, wherein, in the optimizing of the wave pattern layout, the trigonometric function is adjusted such that a curve angle of the trigonometric function is minimized when the wave pattern layout has an arbitrary wave width set.

### CROSS-REFERENCE TO RELATED APPLICATION

This application is based on and claims priority under 35 U.S.C. § 119 to Korean Patent Application No. 10-2025-0006385, filed on Jan. 15, 2025, in the Korean Intellectual Property Office, the disclosure of which is incorporated herein in its entirety by reference.

### BACKGROUND

In a semiconductor process, a photolithography process using a mask may be performed to form a pattern on a semiconductor substrate, such as a wafer. A mask may be simply defined as a pattern transfer material in which a pattern shape of an opaque material is formed on a transparent base material. To briefly describe a mask manufacturing process, first, a demanded circuit is designed, a layout for the circuit is designed, and then design data obtained through OPC is transmitted as mask tape-out (MTO) design data. Thereafter, mask data preparation (MDP) may be performed based on the MTO design data, and an exposure process, etc. may be performed on a mask substrate.

### SUMMARY

The present disclosure relates to an optical proximity correction (OPC) method and a mask manufacturing method including the OPC method.

The present disclosure provides an optical proximity correction (OPC) method having improved reliability and a mask manufacturing method including the OPC method.

According to an aspect of the present disclosure, an optical proximity correction (OPC) method includes inputting a wave pattern layout based on a trigonometric function having a width, a height, and power as variables, generating evaluation points on the wave pattern layout, and optimizing the wave pattern layout based on the evaluation points, wherein, in the optimizing of the wave pattern layout, the trigonometric function is adjusted such that a curve angle of the trigonometric function is minimized when the wave pattern layout has an arbitrary wave width set.

According to another aspect of the present disclosure, a method of manufacturing a mask includes inputting a wave pattern layout based on a trigonometric function having a width, a height, and power as variables, generating evaluation points on the wave pattern layout, and optimizing the wave pattern layout based on the evaluation points, inputting data on the wave pattern layout to an optical proximity correction (OPC) model and extracting a contour of a target pattern through simulation, calculating an edge placement edge (EPE) value, determining whether to perform again the extracting of the contour, when it is determined to perform again the extracting of the contour, re-optimizing the wave pattern layout based on the evaluation points, when it is determined to not to perform again the extracting of the contour, determining the wave pattern layout as an OPC-ed layout, transmitting data regarding the OPC-ed layout as mask tape-out (MTO) design data, preparing mask data based on the MTO design data, and performing exposure on a mask substrate based on the mask data, wherein, in the optimizing of the wave pattern layout, the trigonometric function is adjusted such that a curve angle of the trigonometric function is minimized when the wave pattern layout has an arbitrary wave width set.

According to another aspect of the present disclosure, an optical proximity correction (OPC) method includes inputting a wave pattern layout based on a trigonometric function having a width, a height, and power as variables, generating evaluation points on the wave pattern layout, optimizing the wave pattern layout based on the evaluation points, inputting data on the wave pattern layout to an optical proximity correction (OPC) model and extracting a contour of a target pattern through simulation, calculating an edge placement edge (EPE) value, and determining whether to perform again the extracting of the contour, wherein, in the optimizing of the wave pattern layout, the trigonometric function is adjusted such that a curve angle of the trigonometric function is minimized when the wave pattern layout has an arbitrary wave width set.

### BRIEF DESCRIPTION OF THE DRAWINGS

Implementations of the present disclosure will be more clearly understood from the following detailed description taken in conjunction with the accompanying diagrams in which:

FIG. 1 is a flowchart for describing the processes of an optical proximity correction (OPC) method according to implementations;

FIG. 2 is a conceptual diagram for describing the OPC method of FIG. 1;

FIG. 3 is a flowchart for describing the processes of an OPC method according to implementations;

FIG. 4 is a conceptual diagram for describing the OPC method of FIG. 3;

FIG. 5 is a flowchart for describing the processes of a mask manufacturing method including an OPC method, according to implementations;

FIGS. 6A and 6B are graphs for describing a method of optimizing a wave pattern layout by an OPC method according to implementations; and

FIGS. 7A and 7B are graphs for describing a method of optimizing a wave pattern layout by an OPC method according to implementations.

### DETAILED DESCRIPTION

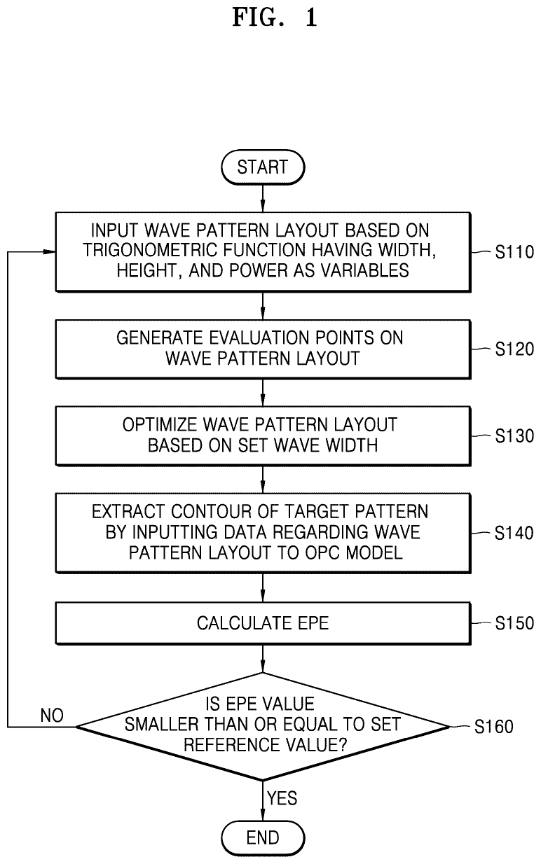

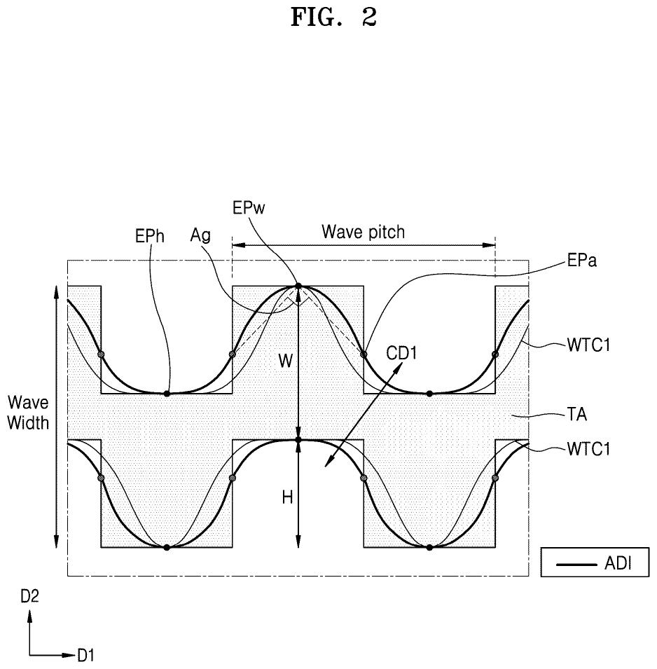

FIG. 1 is a flowchart for describing the processes of an optical proximity correction (OPC) method S100 according to implementations. FIG. 2 is a conceptual diagram for describing the OPC method S100 of FIG. 1.

Referring to FIGS. 1 and 2, a wave pattern layout defined by a first boundary surface WTC1 and a second boundary surface WTC2 may be input first (operation S110).

Here, a wave pattern layout may refer to an OPC target design layout for a target pattern having a wave-like shape to be formed on a substrate such as a wafer. Here, an OPC target design may refer to a layout of a target to perform OPC. A target pattern on a substrate may be formed by transferring a pattern on a mask to the substrate through an exposure process. Therefore, the OPC target design layout may refer to a layout for the pattern on the mask corresponding to the target pattern on the substrate. Since a pattern on a mask is scaled down and projected onto a wafer, the pattern on the mask may have a larger size than a target pattern on a substrate.

According to implementations, the first boundary surface WTC1 defining the wave pattern layout may be expressed by a trigonometric function defined as Equation 1 below.

$$y = \frac{H}{2} {cos}^{p} ( \frac{x}{{pitch}_{x}} * 2 π ) \qquad [ Equation 1 ]$$

In Equation 1, H may represent the height of the trigonometric function, p may represent the power, and pitchₓ may represent the wave pitch. Here, the wave pitch may be equal to the pitch adjacent channel holes adjacent to each other in a first direction D1.

According to implementations, the second boundary surface WTC2 defining the wave pattern layout may be expressed by a trigonometric function defined as Equation 2 below.

$$y = \frac{H}{2} {cos}^{p} ( \frac{x}{{pitch}_{x}} * 2 π ) - W \qquad [ Equation 2 ]$$

In Equation 2, H may represent the height of the trigonometric function, W may represent the width of the trigonometric function, p may represent the power, and pitch may represent the wave pitch. Here, the wave pitch may be equal to the pitch adjacent channel holes adjacent to each other in a first direction D1.

In Equations 1 and 2, the height H of the trigonometric function may refer to a distance in a second direction D2 between a first point EPw generated at the crest of the trigonometric function and a second point EPh generated at the valley of trigonometric functions respectively expressing the first boundary surface WTC1 and the second boundary surface WTC2, and the width W of the trigonometric function may refer to a distance in the second direction D2 between the first point EPw generated at the crest of a trigonometric function having (e.g., following) Equation 1 expressing the first boundary surface WTC1 and the first point EPw generated at the crest of a trigonometric function having (e.g., following) Equation 2 expressing the second boundary surface WTC2.

Next, evaluation points may be generated on the trigonometric function having Equation 1 and the trigonometric function having Equation 2 (operation S120).

In detail, in operation S120, the first point EPw may be generated at the crest of each of the trigonometric function having Equation 1 and the crest of the trigonometric function having Equation 2, the second point EPh may be generated at the valley of each of the trigonometric function having Equation 1 and the valley of the trigonometric function having Equation 2, and third points EPa may be generated at any point between the crest of the trigonometric function having Equation 1 and the valley of the trigonometric function having Equation 1 and any point between the crest of the trigonometric function having Equation 2 and the valley of the trigonometric function having Equation 2.

As described above, in Equations 1 and 2, the height H of the trigonometric function may be defined as a distance in the second direction D2 between the first point EPw generated at the crest of the trigonometric function and the second point EPh generated at the valley of trigonometric functions respectively expressing the first boundary surface WTC1 and the second boundary surface WTC2, and the width W of the trigonometric function may be defined as a distance in the second direction D2 between the first point EPw generated at the crest of a trigonometric function having Equation 1 expressing the first boundary surface WTC1 and the first point EPw generated at the crest of a trigonometric function having Equation 2 expressing the second boundary surface WTC2.

The sum of the height H of a trigonometric function and the width W of the trigonometric function may be named a wave width. The wave width may be the width of a wave pattern layout in the second direction D2.

The curve angle Ag of the trigonometric function may be determined based on the third point EPa and the first point EPw. The curve angle Ag of the trigonometric function may refer to an angle formed when connecting one first point EPw of the trigonometric function having Equation 1 in one period to two third points EPa adjacent to the first point EPw in the one period.

Each of an arbitrary point between the crest of the trigonometric function having Equation 1 at which the third point EPa is generated and the valley of the trigonometric function having Equation 1 and an arbitrary point between the crest of the trigonometric function having Equation 2 at which the third point EPa is generated and the valley of the trigonometric function having Equation 2 may be, for example, a point spaced apart in the second direction D2 by ⅓ of the height H of the trigonometric function from each of the valley of the trigonometric function having Equation 1 and the valley of the trigonometric function having Equation 2. However, the present disclosure is not limited thereto, and arbitrary points at which the third points EPa are generated may be changed depending on the setting values of a contour ADI of a target pattern to be formed on a substrate.

Next, the wave pattern layout may be optimized to have an appropriate diagonal critical dimension CD1 and an appropriate trigonometric curve angle Ag based on a set wave width (operation S130). To implement a target pattern having a wave pattern, the wave pattern layout may be adjusted to have the largest diagonal critical dimension CD1 and the smallest trigonometric curve angle Ag within the set wave width while having a set depth-of-focus (DOF) value. For example, the wave pattern layout may be adjusted by changing the width W of the trigonometric function or the height H of the trigonometric function within the wave width, changing each of the trigonometric function represented by Equation 1 and the trigonometric function represented by Equation 2, or changing the curve angle Ag of the trigonometric function within an allowable range to implement a target pattern having a wave pattern. Here, the diagonal critical dimension CD1 may be a factor affecting the patterning margin in an exposure process using a mask and a development process completed based on an OPC layout optimized through an OPC method according to implementations.

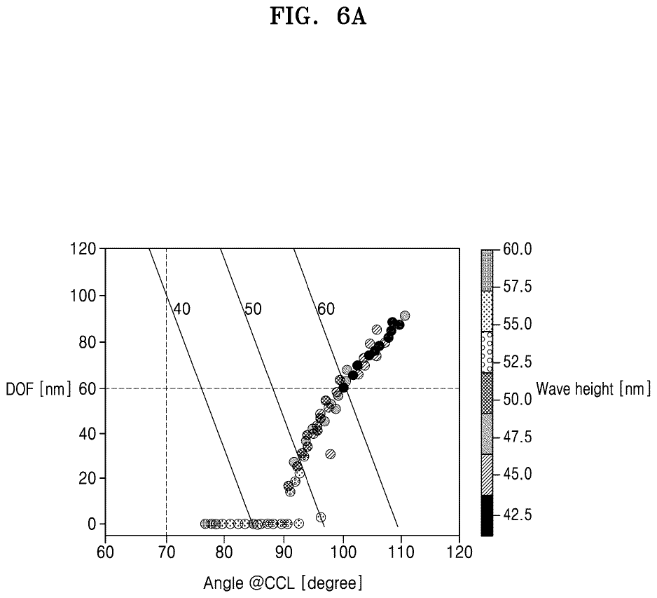

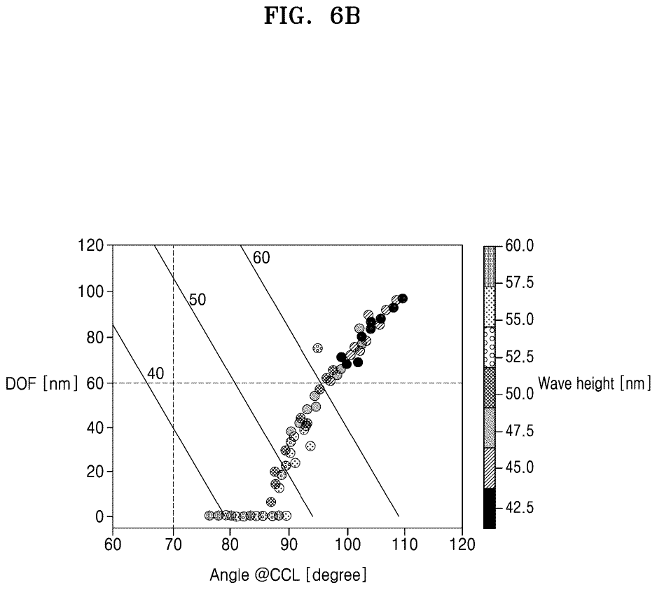

In operation S130, from among several variables defining a wave pattern layout, a process of obtaining data by fixing all variables except for one variable and changing the one variable is repeated, and the wave pattern layout may be optimized based on data obtained through the process. Descriptions thereof will be given below in more detail with reference to FIGS. 6A and 6B.

Next, data regarding the wave pattern layout for which operation S130 has been performed may be input to an OPC model to extract the contour ADI of the target pattern through a simulation (operation S140). In addition, the OPC model is a simulation model for extracting the contour of a target pattern, and various base data may be input as input data to the OPC model. Here, the base data may include mask data, e.g., data regarding a wave pattern layout. Furthermore, the base data may include information such as a thickness, a refractive index, and a dielectric constant for a photoresist (PR) and may include data regarding a source map regarding the shape of an illumination system. However, the present disclosure is not limited thereto.

The contour of a target pattern is a result of simulation using an OPC model, and may correspond to the shape of a target pattern TP formed on a wafer in the exposure process using a mask. Therefore, it may be an objective of the OPC method according to implementations to make the contour ADI as similar as possible to the shape of the target pattern TP.

Next, an edge placement edge (EPE) value is calculated (operation S150), and it may be determined whether a calculated EPE value is less than or equal to a pre-set reference value (operation S160). When the EPE value is not less than the pre-set reference value in operation S160, the OPC method S100 may be performed again. In general, the shape of the contour of the initial target pattern extracted after operation S140 is performed for the first time may deviate significantly from the shape of a target pattern. Therefore, to minimize the difference, the contour of the target pattern is compared to the target pattern, and the OPC target design layout is adjusted to generate a new OPC design layout. Afterwards, data for the new OPC design layout is input to an OPC model, and the contour of the target pattern is extracted again through a simulation. Also, the contour of the target pattern is compared with the target pattern and the OPC target design layout is adjusted to re-generate the OPC design layout. This process may be repeated until a set condition is satisfied. For example, the condition may be set based on the EPE value as in operation S150 described above or based on the number of repetitions. In other words, the process for extraction of the contour of the target pattern may be repeated until the EPE value becomes lower than a set reference value or the number of repetitions reaches a set reference number. Here, the EPE may mean the difference between the contour of a target pattern and a target pattern at an evaluation point. Also, a reference number may be set based on the average number of times or the maximum number of times that the EPE reaches the reference value through simulation using an OPC model. Ultimately, an OPC design layout finally generated through the repetition of the process corresponds to an OPC-ed design layout, and may correspond to an OPC-ed wave pattern layout in the OPC method of the present implementation.

In operation S150, when the EPE value is less than or equal to a pre-set reference value (YES), the OPC method S100 may be terminated. On the other hand, in operation S150, when the EPE value exceeds the pre-set reference value (NO), operations S110 to S140 described above may be performed sequentially again.

A conventional OPC method divides an OPC target design layout into a plurality of segments, generates control points in the plurality of segments, and optimizes the OPC target design layout by using the control points. The conventional OPC method has no problem in extracting the contour of a simple line-shaped target pattern or a rectangular contact target pattern. However, when extracting the contour of a wave-shaped target pattern, it is difficult to extract the contour of a wave-shaped target pattern that is almost similar to a wave-shaped target pattern using the conventional OPC method, because the critical dimension in diagonal directions, the curve angle of a wave-like shape, etc. need to be considered.

On the other hand, unlike the conventional OPC method, the OPC method S100 according to implementations generates a wave pattern layout based on a trigonometric function in implementing a target pattern having a wave-like shape, generates evaluation points on the trigonometric function expressing boundary surfaces defining the wave pattern layout, and optimizes the wave pattern layout based on the evaluation points. Therefore, in the optimization process of a wave pattern layout, variables such as the critical dimensions in diagonal directions and the curve angle of the wave-like shape may be well reflected, and thus the contour of the wave-shaped target pattern that is almost similar to the wave-like shape target pattern may be extracted.

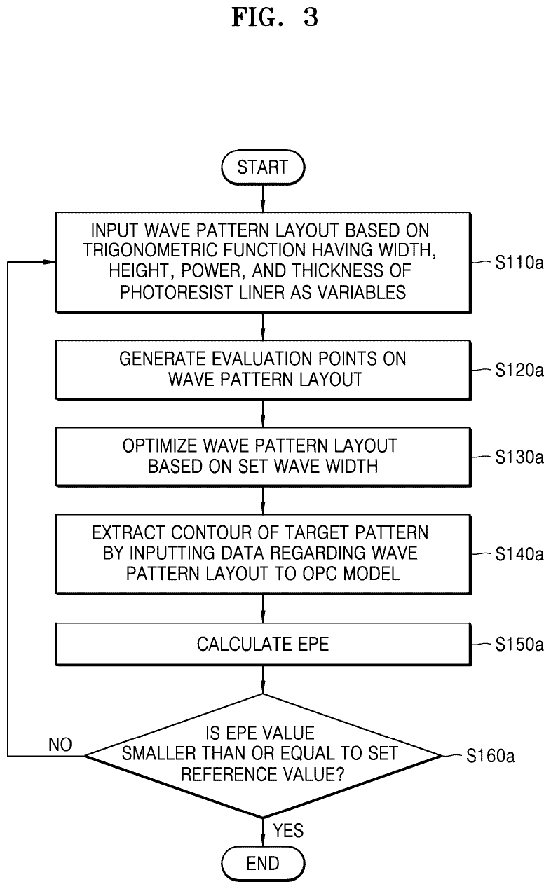

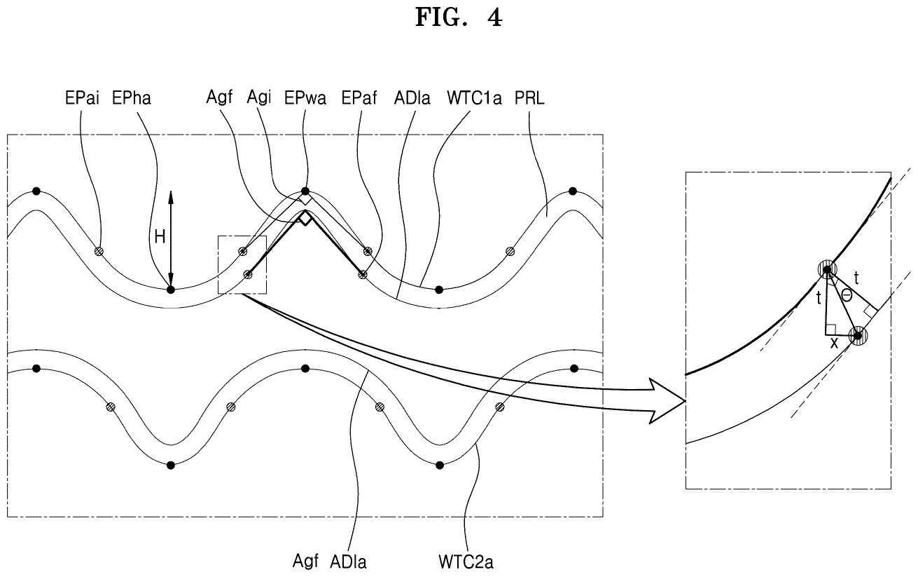

FIG. 3 is a flowchart for describing the processes of an OPC method S100a according to implementations. FIG. 4 is a conceptual diagram for describing the OPC method S100a of FIG. 3.

Referring to FIGS. 3 and 4, a wave pattern layout defined by a first boundary surface WTC1a and a second boundary surface WTC2a may be input first (operation S110a).

According to implementations, the first boundary surface WTC1a defining the wave pattern layout may be expressed by a trigonometric function defined as Equation 3 below.

$$y = \frac{H}{2} {cos}^{p} ( \frac{x}{{pitch}_{x}} * 2 π ) + \frac{C}{cos θ} \qquad [ Equation 3 ]$$

In Equation 3, H may represent the height of the trigonometric function, p may represent the power, and pitchₓ may represent the wave pitch. Here, the wave pitch may be equal to the pitch between channel holes adjacent to each other in the first direction D1. θ may represent

$${tan}^{- 1} \frac{\partial y}{\partial x} ,$$

and C may represent the thickness of the photoresist liner PRL.

According to implementations, the second boundary surface WTC2a defining the wave pattern layout may be expressed by a trigonometric function defined as Equation 4 below.

$$y = \frac{H}{2} {cos}^{p} ( \frac{x}{{pitch}_{x}} * 2 π ) + \frac{C}{cos θ} - W \qquad [ Equation 4 ]$$

In Equation 4, H may represent the height of the trigonometric function, W may represent the width of the trigonometric function, p may represent the power, and pitch may represent the wave pitch. Here, the wave pitch may be equal to the pitch between channel holes adjacent to each other in the first direction D1. θ may represent

$${tan}^{- 1} \frac{\partial y}{\partial x} ,$$

and C may represent the thickness of the photoresist liner PRL.

In Equations 3 and 4, the thickness of the photoresist liner PRL may not be constant throughout the trigonometric functions expressed by Equation 3 and Equation 4, respectively. For example, the thickness of the photoresist liner PRL at an arbitrary point may be different from the thickness of the photoresist liner PRL at another arbitrary point. In other words, the thickness of the photoresist liner PRL in each of Equation 3 and Equation 4 is not a fixed value but may vary.

In the OPC method S100a shown in FIGS. 3 and 4, the first boundary surface WTC1a and the second boundary surface WTC2a defining a wave pattern layout may be defined by trigonometric functions that further consider the thickness of the photoresist liner PRL, as compared to the OPC method S100 shown in FIGS. 1 and 2. In other words, in the OPC method S100a shown in FIGS. 3 and 4, the wave pattern layout may be optimized by further considering the thickness of the photoresist liner PRL as compared to the OPC method S100 shown in FIGS. 1 and 2, and thus the contour of a target pattern that is more similar to the target pattern having a wave-like shape may be extracted through the OPC method S100a.

In Equations 3 and 4, the height H of the trigonometric function may refer to a distance in a second direction D2 between a first point EPwa generated at the crest of the trigonometric function and a second point EPha generated at the valley of trigonometric functions respectively expressing the first boundary surface WTC1a and the second boundary surface WTC2a, and the width W of the trigonometric function may refer to a distance in the second direction D2 between the first point EPwa generated at the crest of a trigonometric function having (e.g., following) Equation 3 expressing the first boundary surface WTC1a and the first point EPwa generated at the crest of a trigonometric function having Equation 4 expressing the second boundary surface WTC2a.

Next, evaluation points may be generated on the trigonometric function having (e.g., following) Equation 3 and the trigonometric function having (e.g., following) Equation 4 (operation S120a).

In detail, in operation S120a, the first point EPwa may be generated at the crest of each of the trigonometric function having Equation 3 and the crest of the trigonometric function having Equation 4, the second point EPha may be generated at the valley of each of the trigonometric function having Equation 3 and the valley of the trigonometric function having Equation 4, and third points EPai may be generated at any point between the crest of the trigonometric function having Equation 3 and the valley of the trigonometric function having Equation 4 and any point between the crest of the trigonometric function having Equation 4 and the valley of the trigonometric function having Equation 4.

As described above, in Equations 3 and 4, the height H of the trigonometric function may be defined as a distance in the second direction D2 between the first point EPwa generated at the crest of the trigonometric function and the second point EPha generated at the valley of trigonometric functions respectively expressing the first boundary surface WTC1a and the second boundary surface WTC2a, and the width W of the trigonometric function may be defined as a distance in the second direction D2 between the first point EPwa generated at the crest of a trigonometric function having Equation 3 expressing the first boundary surface WTC1a and the first point EPwa generated at the crest of a trigonometric function having Equation 4 expressing the second boundary surface WTC2a.

The sum of the height H of a trigonometric function and the width W of the trigonometric function may be named a wave width. The wave width may be the width of a wave pattern layout in the second direction D2.

A curve angle Agi of the trigonometric function may be determined based on a third point EPai and the first point EPwa. The curve angle Agi of the trigonometric function may refer to an angle formed when connecting one first point EPwa of the trigonometric function having Equation 1 in one period to two third points EPai adjacent to the first point EPwa in the one period.

Furthermore, a contour ADIa of a target pattern may be defined within a region defined by the first boundary surface WTC1a and the second boundary surface WTC2a. The contour ADIa of the target pattern may have a shape similar to that of a wave pattern layout, but may be a region located inwardly and spaced apart by “t” from each of the first boundary surface WTC1a and the second boundary surface WTC2a. Here, “t” may refer to the thickness of the photoresist liner PRL, i.e., “C” of Equations 3 and 4.

A curve angle Agf of the contour ADIa of the target pattern may refer to the angle formed by lines interconnecting a point EPaf on the contour ADIa of the target pattern that is aligned with the third point EPai in the first direction D1 and a point EPwf on the contour ADIa of the target pattern that is aligned with the first point EPwa in the second direction D2.

When the curve angle Agf of the contour ADIa of the target pattern is compared with the curve angle Agi of the trigonometric function, it may be seen that the curve angle Agf of the contour ADIa of the target pattern is less than the curve angle Agi of the trigonometric function. In other words, when a wave pattern layout is generated based on Equations 3 and 4 that further consider the thickness of the photoresist liner PRL, the curve angle Agf of the contour ADIa of the target pattern may smaller as compared to that of the case where a wave pattern layout is generated without considering the thickness of the photoresist liner PRL.

Each of an arbitrary point between the crest of the trigonometric function having Equation 3 at which the third point EPai is generated and the valley of the trigonometric function having Equation 3 and an arbitrary point between the crest of the trigonometric function having Equation 4 at which the third point EPai is generated and the valley of the trigonometric function having Equation 4 may be, for example, a point spaced apart in the second direction D2 by ⅓ of the height H of the trigonometric function from each of the valley of the trigonometric function having Equation 3 and the valley of the trigonometric function having Equation 4. However, the present disclosure is not limited thereto, and arbitrary points at which the third points EPa are generated may be changed depending on the setting values of a contour ADI of a target pattern to be formed on a substrate.

Next, the wave pattern layout may be optimized to have an appropriate diagonal critical dimension CD1 and an appropriate trigonometric curve angle Agi based on a set wave width (operation S130a). To implement a target pattern having a wave pattern, the wave pattern layout may be adjusted to have the largest diagonal critical dimension CD1 and the smallest trigonometric curve angle Ag within the set wave width while having a set DOF value. For example, the wave pattern layout may be adjusted by changing the width W of the trigonometric function or the height H of the trigonometric function within the wave width, changing each of the trigonometric function represented by Equation 3 and the trigonometric function represented by Equation 4, or changing the curve angle Ag of the trigonometric function within an allowable range to implement a target pattern having a wave pattern.

In operation S130a, from among several variables defining a wave pattern layout, a process of obtaining data by fixing all variables except for one variable and changing the one variable is repeated, and the wave pattern layout may be optimized based on data obtained through the process. Descriptions thereof will be given below in more detail with reference to FIGS. 6A and 6B.

Next, data regarding the wave pattern layout for which operation S130a has been performed may be input to an OPC model to extract the contour ADI of the target pattern through a simulation (operation S140a).

Next, an EPE value is calculated (operation S150a), and it may be determined whether a calculated EPE value is less than or equal to a pre-set reference value (operation S160a). When the EPE value is not less than the pre-set reference value in operation S150a, the OPC method S100a may be performed again.

In operation S150a, when the EPE value is less than or equal to a pre-set reference value (YES), the OPC method S100a may be terminated. On the other hand, in operation S150a, when the EPE value exceeds the pre-set reference value (NO), operations S110a to S140a described above may be performed sequentially again.

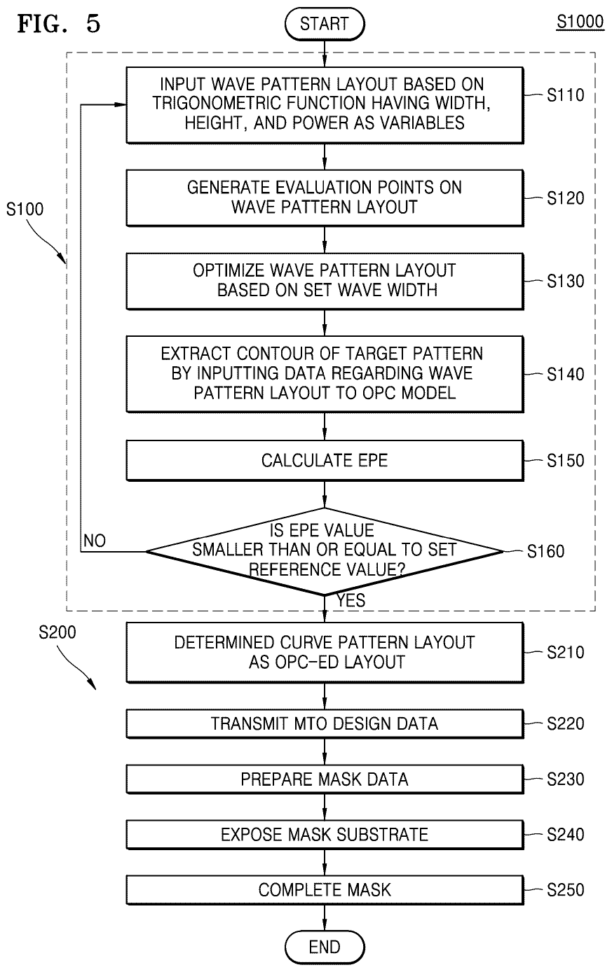

FIG. 5 is a flowchart for describing the processes of a mask manufacturing method S1000 including an OPC method, according to implementations.

Referring to FIG. 5, the mask manufacturing method S1000 may first include an operation for performing the OPC method S100. Although FIG. 5 shows that the OPC method S100 shown in FIGS. 1 and 2 is performed, the present disclosure is not limited thereto, and the OPC method S100a shown in FIGS. 3 and 4 may also be performed. Since operations of an OPC method have been described in detail with reference to FIGS. 1 to 4, detailed descriptions of operations the OPC method in the mask manufacturing method S1000 according to implementations are omitted.

After the OPC method is performed, a wave pattern layout may be determined as an OPC layout (operation S210).

Next, MTO design data may be transferred to a mask production team (operation S220). In general, MTO may refer to handing over data regarding a pattern layout on a final mask obtained through an OPC method to the mask manufacturing team to request manufacturing of a mask. Therefore, in the mask manufacturing method according to implementations, the MTO design data may ultimately be substantially identical to OPC-ed data obtained through the OPC method, i.e., data regarding the wave pattern layout (e.g., optimized wave pattern layout). Such MTO design data may have a graphic data format used in electronic design automation (EDA) software, etc. For example, the MTO design data may have a data format such as Graphic Data System II (GDS2), Open Artwork System Interchange Standard (OASIS), etc.

Thereafter, mask data preparation (MDP) may be performed (operation S230). The MDP may include, for example, i) format conversion, called fracturing, ii) augmentation of barcodes for mechanical reading, a standard mask pattern for inspection, a job deck, etc., and iii) automatic and manual verification. Here, a job-deck may refer to generation of a text file regarding a series of instructions such as arrangement information of multiple mask files, a standard dose, and a speed or a method of exposure.

The format conversion, i.e., fracturing, may refer to a process of dividing MTO design data into respective regions and converting the MTO design data to a format for electron beam exposure equipment. The fracturing may include data manipulation, such as scaling, sizing of data, rotating of data, reflecting a pattern, and inverting colors. During a conversion process through fracturing, data regarding a large number of systematic errors that may occur somewhere during transmission from design data to an image on a wafer may be corrected.

The process of correction of data regarding systematic errors is called mask process correction (MPC) and may include, for example, a task for adjusting a line width called CD adjustment and a task for improving pattern placement precision. Therefore, the fracturing may contribute to improving the quality of a final mask and may also be a process that is performed in advance for MPC. Here, the systematic errors may be caused by distortion occurring in an exposure process, a mask development and etching process, and a wafer imaging process.

In addition, the MDP may include the MPC. As described above, the MPC refers to a process of correcting errors that occur during an exposure process, that is, systematic errors. Here, the exposure process may be an overall concept that includes electron beam writing, development, etching, baking, etc. Also, data processing may be performed prior to the exposure process. The data processing is a preprocessing process regarding mask data and may include grammar check for mask data, exposure time prediction, etc.

Next, after preparing the mask data, a mask substrate may be exposed based on the mask data (operation S240). Here, the exposure may mean, for example, electron beam writing. Here, the electron beam writing may be performed, for example, through a gray writing method using a multi-beam mask writer (MBMW). Also, the E-beam writing may also be performed using variable shape beam (VSB) exposure equipment.

Furthermore, after the MDP, a process of converting the mask data into pixel data may be performed before an exposure process. Pixel data is data directly used for actual exposure and may include data regarding a shape to be exposed and data regarding the dose assigned to each shape. Here, the data regarding a shape may be bit-map data obtained by converting shape data, which is vector data, through rasterization or the like.

After operation S240, a series of processes may be performed to complete a mask (operation S250). The series of processes may include, for example, development, etching, and cleaning. Also, a series of processes of manufacturing a mask may include a metrology process, a defect inspection process, or a defect repair process. Furthermore, the series of processes of manufacturing a mask may include a pellicle application process. Here, the pellicle application process may refer to a process of attaching pellicles to a mask surface to protect a mask from subsequent contamination during delivery and during the useful life of the mask when it is confirmed that there are no contaminant particles or chemical stains through final cleaning and inspection.

FIGS. 6A and 6B are graphs for describing a method of optimizing a wave pattern layout by an OPC method according to implementations. FIG. 6A is a graph showing data of a wave pattern layout having an ideal profile when the wave width is 135 nm, and FIG. 6B is a graph showing data of a wave pattern layout having an ideal profile when the wave width is 140 nm. In FIGS. 6A and 6B, the horizontal axis may represent the curve angle Ag of the trigonometric function described with reference to FIG. 2 (refer to FIG. 2), the vertical axis on the left may represent the DOF, the vertical axis on the right may represent the height H of the trigonometric function described with reference to FIG. 2, and the diagonal line may represent the diagonal critical dimension CD1 described with reference to FIG. 2.

Referring to FIG. 6A, for example, in the wave pattern layout having a wave width set to 135 nm, when implementing the DOF of 60 nm and the diagonal critical dimension CD1 of about 60 nm, it may be confirmed that the curve angle of the wave pattern layout having an ideal profile is about 100 degrees.

Referring to FIG. 6B, for example, in the wave pattern layout having a wave width set to 140 nm, when implementing the DOF of 60 nm and the diagonal critical dimension CD1 of about 60 nm, it may be confirmed that the curve angle of the wave pattern layout having an ideal profile is about 95 degrees.

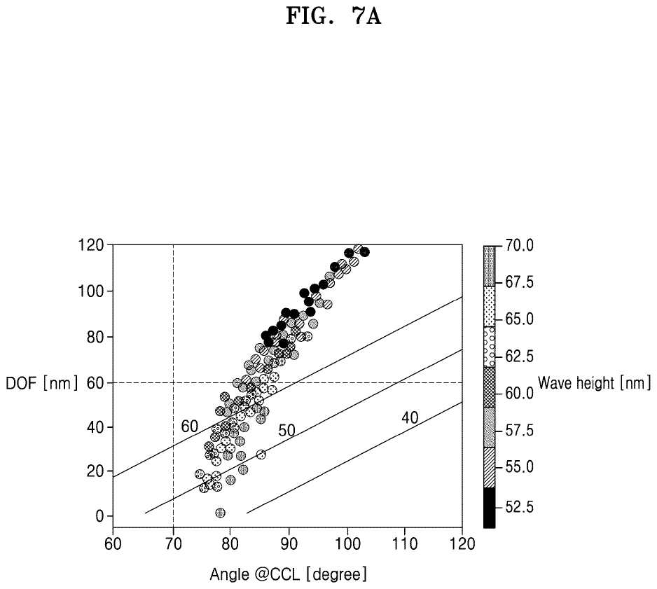

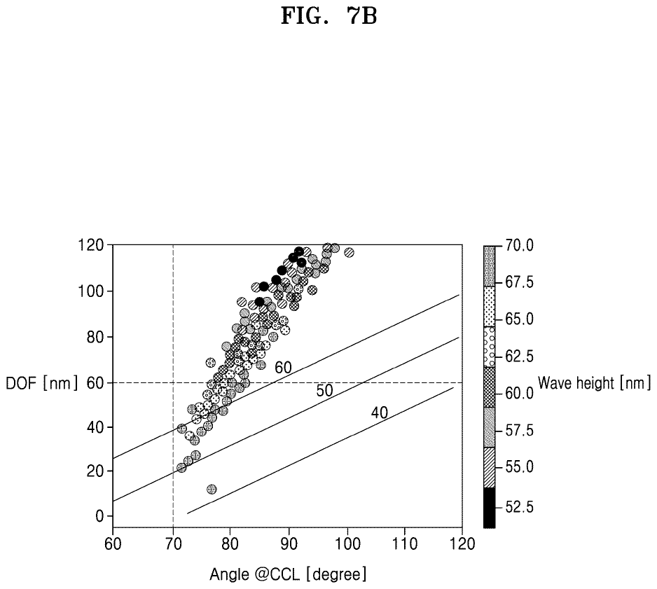

FIGS. 7A and 7B are graphs for describing a method of optimizing a wave pattern layout by an OPC method according to implementations. FIG. 7A is a graph showing data of a wave pattern layout having an ideal profile when the thickness of the photoresist liner PRL (refer to FIG. 4) is 10 nm, and FIG. 7B is a graph showing data of a wave pattern layout having an ideal profile when the thickness of the photoresist liner PRL (refer to FIG. 4) is 15 nm. In FIGS. 7A and 7B, the wave width may be 140 nm, the horizontal axis may represent the curve angle Ag of the trigonometric function described with reference to FIG. 2 (refer to FIG. 2), the vertical axis on the left may represent the DOF, the vertical axis on the right may represent the height H of the trigonometric function described with reference to FIG. 2, and the diagonal line may represent the diagonal critical dimension CD1 described with reference to FIG. 2.

Referring to FIG. 7A, for example, in a wave pattern layout where the thickness of the photoresist liner PRL (refer to FIG. 4) is set to 10 nm, when implementing the DOF of 60 nm and the diagonal critical dimension CD1 of about 60 nm, it may be confirmed that the curve angle of the wave pattern layout having an ideal profile is about 92 degrees.

Referring to FIG. 7B, for example, in a wave pattern layout where the thickness of the photoresist liner PRL (refer to FIG. 4) is set to 15 nm, when implementing the DOF of 60 nm and the diagonal critical dimension CD1 of about 60 nm, it may be confirmed that the curve angle of the wave pattern layout having an ideal profile is about 95 degrees.

In other words, referring to FIGS. 7A and 7B, when optimizing the wave pattern layout according to the OPC method S100a considering the thickness of the photoresist liner PRL (refer to FIG. 4), the curve angle of the trigonometric function defining the wave pattern layout may be further reduced.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An optical proximity correction (OPC) method comprising:
inputting, using a controller, a wave pattern layout based on a trigonometric function, the trigonometric function having a width, a height, and power as variables;
generating, using the controller, evaluation points on the wave pattern layout; and
optimizing, using the controller, the wave pattern layout based on the evaluation points,
wherein optimizing the wave pattern layout includes adjusting the trigonometric function to minimize a curve angle of the trigonometric function based on the wave pattern layout having a set wave width.

2. The OPC method of claim 1, wherein
inputting the wave pattern layout comprises defining the wave pattern layout based on a first boundary surface following Equation 1 below and a second boundary surface following Equation 2 below,
$$y = \frac{H}{2} {cos}^{p} ( \frac{x}{{pitch}_{x}} * 2 π ) \qquad [ Equation 1 ]$$
$$y = \frac{H}{2} {cos}^{p} ( \frac{x}{{pitch}_{x}} * 2 π ) - W \qquad [ Equation 2 ]$$
wherein in Equations 1 and 2, H represents the height of the trigonometric function, W represents the width of the trigonometric function, p represents the power, and pitchₓ represents a wave pitch.

3. The OPC method of claim 1, comprising:
inputting data on the wave pattern layout to an OPC model and extracting a contour of a target pattern based on simulation of the OPC model;
calculating an edge placement edge (EPE) value; and
determining to extract the contour again.

4. The OPC method of claim 1, wherein generating the evaluation points on the wave pattern layout comprises:
generating a first point at a crest of the trigonometric function;
generating a second point at a valley of the trigonometric function; and
generating a third point that is between the crest of the trigonometric function and the valley of the trigonometric function.

5. The OPC method of claim 4, wherein
the height of the trigonometric function is based on the first point and the second point, the width of the trigonometric function is based on the first point, and the curve angle of the trigonometric function is based on the third point.

6. The OPC method of claim 1, wherein optimizing the wave pattern layout comprises:
optimizing the wave pattern layout based on a diagonal critical dimension of the trigonometric function.

7. The OPC method of claim 1, wherein the trigonometric function includes a thickness of a photoresist liner as a variable.

8. The OPC method of claim 7, wherein
inputting the wave pattern layout comprises defining the wave pattern layout based on a first boundary surface following Equation 3 below and a second boundary surface following Equation 4 below,
$$y = \frac{H}{2} {cos}^{p} ( \frac{x}{{pitch}_{x}} * 2 π ) + \frac{C}{cos θ} \qquad [ Equation 3 ]$$
$$y = \frac{H}{2} {cos}^{p} ( \frac{x}{{pitch}_{x}} * 2 π ) + \frac{C}{cos θ} - W \qquad [ Equation 4 ]$$
wherein, in Equations 3 and 4, H represents the height of the trigonometric function, W represents the width of the trigonometric function, p represents the power, pitchₓ represents a wave pitch, θ represents
$${tan}^{- 1} \frac{\partial y}{\partial x} ,$$
and C represents the thickness of the photoresist liner.

9. The OPC method of claim 7, wherein the thickness of the photoresist liner is variable.

10. The OPC method of claim 1, wherein the wave pattern layout has a shape of a curved line.

11. A method of manufacturing a mask, the method comprising:
inputting a wave pattern layout based on a trigonometric function, the trigonometric function having a width, a height, and power as variables;
generating evaluation points on the wave pattern layout;
optimizing the wave pattern layout based on the evaluation points;
inputting data on the optimized wave pattern layout to an optical proximity correction (OPC) model and extracting a contour of a target pattern based on simulation of the OPC model;
calculating an edge placement edge (EPE) value;
performing at least one of
(i) based on determining to extract the contour again, re-optimizing the wave pattern layout based on the evaluation points, or
(ii) based on determining to not extract the contour again, determining the optimized wave pattern layout as an OPC-ed layout;
transmitting data associated with the OPC-ed layout as mask tape-out (MTO) design data;
preparing mask data based on the MTO design data; and
performing exposure on a mask substrate based on the mask data,
wherein optimizing the wave pattern layout comprises adjusting the trigonometric function to minimize a curve angle of the trigonometric function based on the wave pattern layout having a set wave width.

12. The method of claim 11, wherein
inputting the wave pattern layout comprises defining the wave pattern layout based on a first boundary surface following Equation 1 below and a second boundary surface following Equation 2 below,
$$y = \frac{H}{2} {cos}^{p} ( \frac{x}{{pitch}_{x}} * 2 π ) \qquad [ Equation 1 ]$$
$$y = \frac{H}{2} {cos}^{p} ( \frac{x}{{pitch}_{x}} * 2 π ) - W \qquad [ Equation 2 ]$$
wherein, in Equations 1 and 2, H represents the height of the trigonometric function, W represents the width of the trigonometric function, p represents the power, and pitchₓ represents a wave pitch.

13. The method of claim 11,
wherein generating the evaluation points on the wave pattern layout comprises:
generating a first point at a crest of the trigonometric function;
generating a second point at a valley of the trigonometric function; and
generating a third point that is between the crest of the trigonometric function and the valley of the trigonometric function.

14. The method of claim 13,
wherein the height of the trigonometric function is based on the first point and the second point, the width of the trigonometric function is based on the first point, and the curve angle of the trigonometric function is based on the third point.

15. The method of claim 11, wherein the trigonometric function includes a thickness of a photoresist liner as a variable.

16. The method of claim 15,
wherein inputting the wave pattern layout comprises defining the wave pattern layout based on a first boundary surface following Equation 3 below and a second boundary surface following Equation 4 below,
$$y = \frac{H}{2} {cos}^{p} ( \frac{x}{{pitch}_{x}} * 2 π ) + \frac{C}{cos θ} \qquad [ Equation 3 ]$$
$$y = \frac{H}{2} {cos}^{p} ( \frac{x}{{pitch}_{x}} * 2 π ) + \frac{C}{cos θ} - W \qquad [ Equation 4 ]$$
wherein, in Equations 3 and 4, H represents the height of the trigonometric function, W represents the width of the trigonometric function, p represents the power, pitchₓ represents a wave pitch, θ represents
$${tan}^{- 1} \frac{\partial y}{\partial x} ,$$
and C represents the thickness of the photoresist liner.

17. The method of claim 15, wherein the thickness of the photoresist liner is variable.

18. An optical proximity correction (OPC) method comprising:
inputting a wave pattern layout based on a trigonometric function, the trigonometric function having a width, a height, and power as variables;
generating evaluation points on the wave pattern layout;
optimizing the wave pattern layout based on the evaluation points;
inputting data on the wave pattern layout to an OPC model and extracting a contour of a target pattern based on a simulation of the OPC model;
calculating an edge placement edge (EPE) value; and
determining to extract the contour again,
wherein optimizing the wave pattern layout comprises adjusting the trigonometric function to minimize a curve angle of the trigonometric function based on the wave pattern layout having a set wave width.

19. The OPC method of claim 18, wherein optimizing the wave pattern layout comprises:
optimizing the wave pattern layout based on a diagonal critical dimension of the trigonometric function.

20. The OPC method of claim 18, wherein the trigonometric function includes a thickness of a photoresist liner as a variable.
